(19) United States
(12) Patent Application Publication
(10) Pub. No.: US 2008/0225915 A1
(43) Pub. Date: Sep. 18, 2008

(54) Method and Apparatus for Prevention of Laser Saturation

(75) Inventor: James Joseph Anthony McCormack, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/813,101

(22) PCT Filed: Jan. 5, 2006
(86) PCT No.: PCT/IB2006/050045

§ 371 Date: Jun. 29, 2007

Related U.S. Application Data
(60) Provisional application No. 60/642,684, filed on Jan. 10, 2005.

(51) Int. Cl. H01S 5/0683; G11B 7/125; G11B 19/28

(52) U.S. Cl. 372/38.02

(57) ABSTRACT

A method and apparatus for preventing laser current saturation (18) in high-speed optical drives. Saturation in laser current in high-speed optical drives is prevented before limitations in laser power are observed allowing the system to maintain requests for increases in the laser power. The saturation in laser current problem that is apparent at high temperatures and at high writing powers especially when combined with low supply voltage is avoided by insured operation of the laser near but below saturation. The ability to increase laser power upon request is maintained providing for good writing quality resulting and usable. The potential onset of laser current saturation is detected (34) and avoided (36) by dropping to a lower write speed requiring less laser power and hence preventing laser current saturation.

The present invention relates to voltage-current characteristics in semiconductor lasers, and more particularly, to preventing saturation during writing for semiconductor lasers used within optical disc technology.

Semiconductor lasers are used within optical disc drives to write information onto optical mediums. Semiconductor lasers have voltage-current characteristics that are similar to diodes. For example in lasers employed by optical disc writers, a current input of about 1 mA results in about 0.7V voltage drop across the laser. This drop can be larger depending on the laser wavelength and composition/construction. The voltage across the laser rises with respective increases in current. The electrical resistance quickly dominates this rise in voltage through the laser, generally referred to as the differential resistance. Semiconductor lasers also have power-current characteristics that result in no laser light being emitted until a current level is reached (known as the threshold current). Above the threshold current, the power level of the laser rises substantially linearly with corresponding rises in current until saturation is reached. Saturation begins to occur at higher power levels and results in a shift in the laser characteristics is requiring higher currents be applied to achieve the same power level from the laser. The saturation problem occurs more readily at higher temperatures. Furthermore, systems do not allow the laser to be drive excessively into saturation for prolonged periods because do so would be detrimental to laser lifetime.

The laser is typically driven from a driver having a current source attached to a supply rail. The peak laser voltage rises with corresponding increases in peak current input into the supply rail to a level wherein the current source driver hits its saturation limit during laser pulse peaks. Once saturation is reached, no further increase in current is possible by changing the drive settings on the current source unless the supply voltage is increased.

Conventional drives are designed based upon the assumption that once optimum power calibration (OPC) is determined, the laser power as determined by the OPC can always be met. A problem exists in that this assumption is not valid in newer classes of optical drives that are currently being made. These newer drives commonly employ Partial Constant Angular Velocity (PCAV) writing profiles. In PCAV writing profiles, the OPC is usually determined at a lower write speed than would occur during writing on the outside of the disc. Writing on the outside of the disc requires higher laser currents. The writing powers that are applied at these lower write speeds can be so high that the temperature rises significantly during the writing process causing the laser current demand to increase dramatically as well. Tests during 16× drive development have shown that laser power can decrease at the highest writing speeds under certain conditions. This decrease in laser power can go undetected by the 16× drive resulting in poor writing quality and bad recordings that are unknown to the drive.

Attempts have been made to correct saturation problems. These attempts have employed techniques that actively monitor the media during the writing process. In drives that write using Zoned Constant Linear Velocity (ZCLV), these prior art techniques involve monitoring the media. If, during monitoring using ZCLV, errors start being produced during writing to the media, drive speeds and consequently the required laser power can be decreased. Using ZCLV, prior art techniques involve decreasing laser power through different zones of the media. In drives that write using CAV, a similar technique is employ but instead of adjustments being made in zones, the drive readjusts the laser power and media speed every minute. Additionally, attempts have been made to correct potential occurrences of laser saturation by monitoring of a thermal circuit inside drive. Once the thermal circuit activates, then the drive reduces the write speed and laser strength. The problem with these prior art approaches is that the actual threshold of laser saturation is not taken in account and absent these actions to prevent laser saturation; they do not provide a truly efficient manner of writing on the optical disc.

From the foregoing discussion, it should be readily apparent that there remains a need within the art for a method and apparatus that can prevent laser saturation in a more efficient manner.

The invention addresses the shortcomings within the prior art drives for preventing laser current saturation. The invention allows operation at the edge of saturation during writing to optical disc media. Operation at the edge of saturation means that the highest possible peak laser power can be used that is practical at that given moment and resulting in the highest writing speed being achieved that is practical at that given moment. The problem of bad recordings due to laser current saturation during writing is avoided by detecting the potential onset of laser current saturation and avoiding laser current saturation writing at a slower speed, and even more optimally, writing at the speed that matches the available peak laser power at the edge of saturation.

The invention detects impending laser current saturation and avoids problems associated with laser current saturation by reducing writing speed in a controlled manner.

The laser current is sensed using a part of the laser power control loop. Detection is accomplished by setting a threshold detection level within the power control loop and controlling the laser power such that no current or power saturation can occur. The invention therefore, maximizes write speeds by maintaining write speeds under the threshold value so that no current or power saturation can occur.

Upon detection of a threshold violation, the drive software initiates a spin-down within the datapath part of the drive. In this procedure the current block of data is written at the current writing speed, a link point is created and the writing is restarted at a lower speed. This lower speed immediately results in lower laser power requirements, thus lower laser current requirements.

Alternatively the drive can react by lowering the writing speed by small (incremental or continuous) amounts without interrupting the writing process. In another embodiment the drive reacts by holding the writing speed at the current value, changing over from a (P)CAV writing profile to a CLV one at the given writing speed.

These objects of the invention are provided for by: monitoring current within a laser; comparing current within the laser with a predetermined threshold; and controlling current within the laser such that current within the laser does not exceed the predetermined threshold.

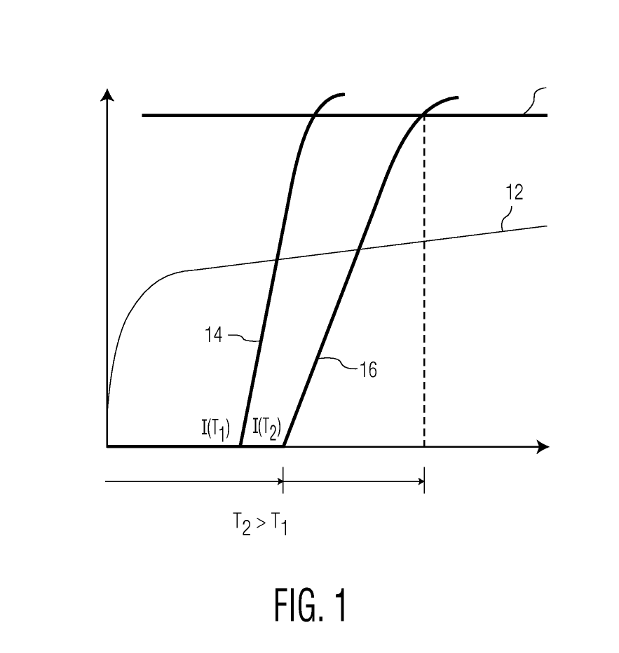

FIG. 1 is a diagram illustrating the laser power characteristics;

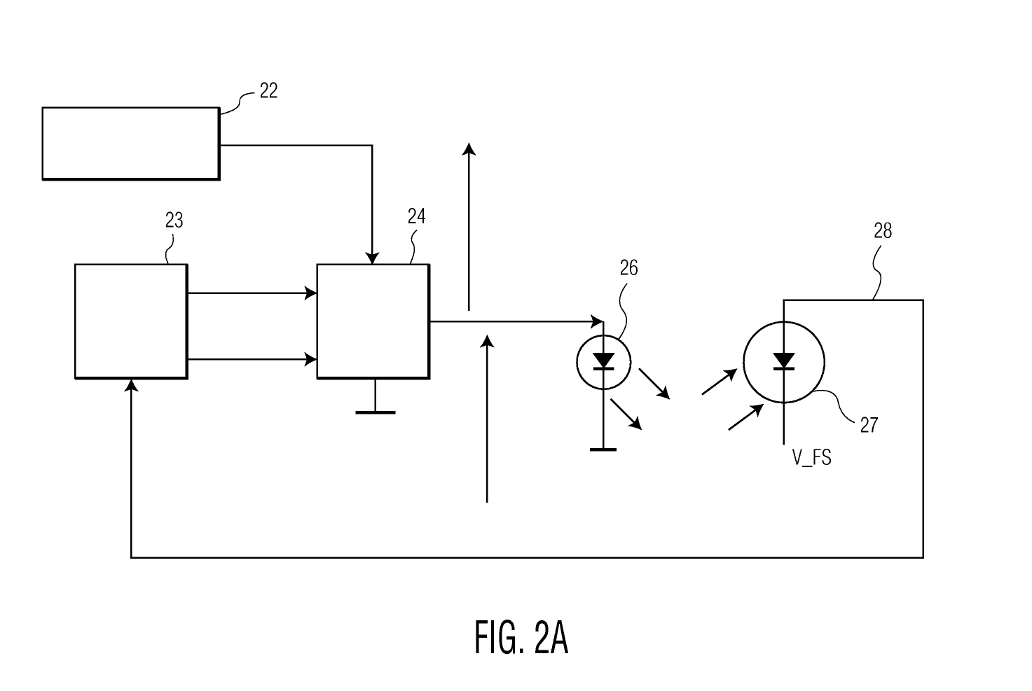

FIG. 2a is a diagram for a laser with a sensor and a feed back loop using a classic driver configuration, which sources current to the laser;

FIG. 2b shows an alternative to FIG. 2a with a laser with a sensor and a feed back loop but using a driver configuration, which sinks current from the laser;

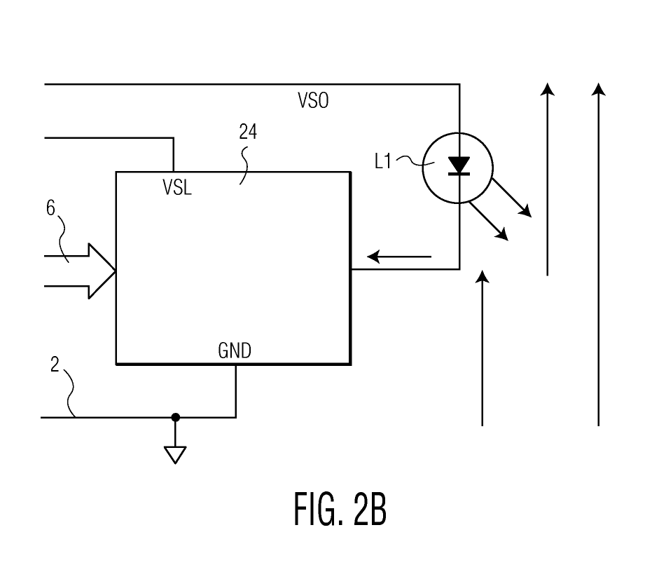

FIG. 3 is a flow chart for determining if laser current is too high;

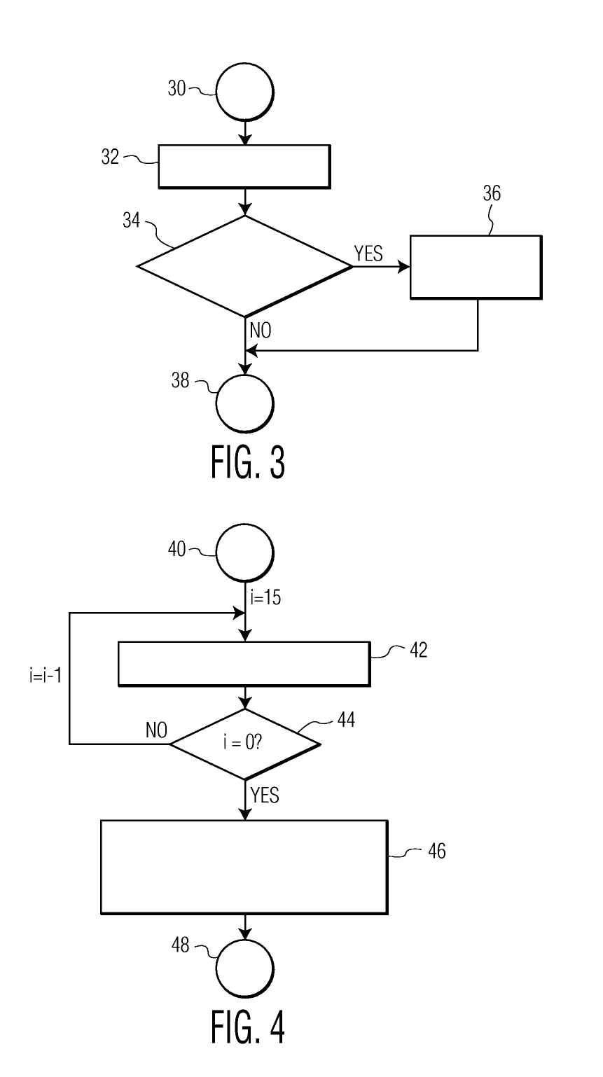

FIG. 4 is a flow chart for calculating the laser current;

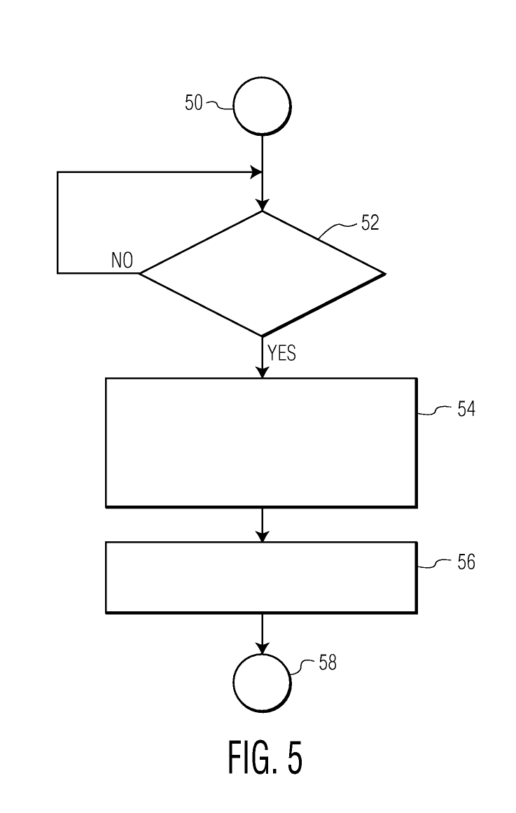

FIG. 5 is a diagram of the routine that performs a spin down of the optical disc as envisioned by the present invention.

Referring to FIG. 1, a diagram of laser characteristics for power and voltage on the Y-axis is illustrated versus laser current on the X-axis. The laser power characteristics are shown as Pₗₐₛₑᵣ(T₁) 14 and Pₗₐₛₑᵣ(T₂) 16. The laser voltage in indicated by Vₗₐₛₑᵣ 12. As shown in FIG. 1, a certain amount of laser current (Iₗₐₛₑᵣ) is required before any power is output by the laser. The power-current characteristics of lasers result in no laser light being emitted until a current level is reached (known as the threshold current). Once the threshold current is reached, the power level of the laser rises linearly with corresponding rises in current until saturation is reached. Saturation begins to occur in FIG. 1 at the indicated as saturation line 18. Above the saturation line 18 level, greater amounts of current are required to achieve the same increases in power that can be obtained below the level shown by saturation line 18. Once the power level is above the level shown by saturation line 18, a shift in the laser characteristics occurs requiring higher currents be applied to achieve the same power level from the laser. This is the point where saturation begins. As illustrated in FIG. 1, the laser power characteristics Pₗₐₛₑᵣ(T₁) 14 and Pₗₐₛₑᵣ(T₂) 16 are offset with respect to each other. This offset is an illustration of Pₗₐₛₑᵣ(T₁) 14 being at a first temperature T₁ and Pₗₐₛₑᵣ(T₂) 16 being that characteristics of the same laser at a second temperature T₂: wherein T_{2>}T₁. As shown in FIG. 1, Pₗₐₛₑᵣ(T₂) 16 continually requires more current to achieve the same power level and the saturation problem occurs more readily at higher temperatures.

As evident from FIG. 1, laser based driver systems develop problems above the level shown by saturation line 18 that and result in a situation wherein the laser current necessary to generate the desired write power reaches a level that too high to further increase laser voltage. At this point the system begins to become unresponsive to further increases in current and reaches the point where the laser can no longer respond to requests for increased laser power. If correct writing is to be insured, writing must be accomplished using a reduced laser current. Reducing the writing speed has the effect of reducing the power required for writing and also the laser current necessary to generate that writing power. It should be noted that for simplicity only one voltage line, Vₗₐₛₑᵣ 12, is drawn but should be recognized that at higher temperatures the laser threshold voltage and resistance can decrease resulting in a shift of this line, typically downwards with reduced slope.

High laser currents are primarily caused due to increases in temperature and increases in writing speed. In the case of systems employing Partial Constant Angular Velocity (PCAV) profiles, writing begins at a lower initial speed closer to the center of the media and progresses to higher final speeds towards the outside edge of the media, resulting in simultaneous increases in temperature and writing speed. Furthermore, the PCAV profiles necessitate that writing at the outside of the media be done at the highest writing speed used in the system, this is the limit case for the laser optimum power calibration (OPC) dimensioning.

In systems using Constant Linear Velocity (CLV) profiles, problems related to increases in temperature and writing speed do not occur to such an extent because the writing power is fixed at OPC. Within CLV profiles, only temperature rises during recording can result in saturation problems.

FIG. 3 is a flow chart illustrating the preferred manner that the invention employs to examine laser current to test is the laser is approaching saturation. The invention envisions that a saturation safety net be built into the system that detects instances wherein the laser power has reached, or is about to reach, the saturation limit. The safety net routine begins by entering Laser Current too High 30 at which point Check Delta_Actual 32 performs a check on the laser current that is presently being used, preferably about every second. The routine Check_Delta_Actual is shown in more detail in FIG. 4. The safety net employs a programmable value called Max_Allowable_Value as a maximum level for peak the laser current, which in the in the preferred embodiment is represented by a value 250 within an 8-bit digital system. Max_Allowable_Value will be typically around 2.5 mA. There is a scaling DAC in the LDD that allows the value of Islope to be matched to the maximum required value of K*Islope for the laser. In typical operation, the maximum value for K is 120 but it can be safely set in the range 40-120. In this way a reference value referred to herein as Islope operates typically between 0-2.5 mA and the LDD amplifies the Islope value by a factor K within the preferred embodiment to produce the peak laser current above threshold. Peak current is the current required to make the peak laser pulse power. Once the Max_Allowable_Value for Delta_Actual is reached, a determination in then made that the Laser Current is so high that reaching saturation is apparent and the routine initiates a Callback to Datapath 36, which actuates a spin-down algorithm from the Datapath via the callback mechanism. The Datapath, as referred to herein, is the process in the drive that controls the flow of information from the Host (typically a personal computer based processing element) to the Encoder. The Datapath process is capable of controlling the writing speed including determining how fast Host data is encoded. The invention indicates to the Datapath process the occurrence of the situation that the laser current is too high so Datapath can determine the course of action. The reaction of Datapath to the callback will quite often by a spin-down algorithm because in a typical application Datapath will reduce the writing speed by spinning down disc rotational speed and writing to the optical disc media at a slower rate. Additional strategies can also be implemented by Datapath, including more sophistic strategies allowing increased throughput by shorter disc writing time. One strategy in a CAV type of writing mode is to hold the present writing speed (which essentially enters a CLV writing mode from this moment on), the spinning speed drops then automatically and smoothly without the need to break recording. Another strategy within CLV/ZCLV recording modes is to reduce the spinning speed gradually to a new lower speed without breaking off the recording process.

Within the preferred embodiment of the invention, it is envisioned that product performance can be maximized if procedures are instituted to insure that the spin down algorithm activates as rarely as possible. In order to ensure that the determination of laser saturation occurs as rarely as possible, the Laser Power Adjustment (LPA) within the drive is first redefined to the extent that it will allow for as much as a 10% adjustment spread while keeping the detection level in mind. These spreads are due to drive and adjustment tolerances in the relationship between I_slope and laser power. The foregoing has been determined based on measurements performed during the development phase using an oven. Based on these tests the LPA setting for the laser powers (for each and every color) has been tuned to achieve this. This methodology serves to eliminate adjustment spread as a potential cause for false spin-down.

FIG. 2a is a diagram of the laser drive system as envisioned by the present invention having a feed back loop used to sense laser power. This is the present configuration of the invention. The detection of the laser power is performed by Forward Sense 27 that generates a feedback signal 28 to Laser Power Control (LPC) 23. Forward Sense 27 is preferably a photodetector that detects a small linear percentage of the laser output and sends feedback signal 28 to represent the present amount of laser power. Numerous additional detection schemes exist that can employed for a determination of laser power. The forward sense control can go directly to LPC 23 or via the LDD 24. Another variant is that FS 27 is made by a PDIC and delivers a direct voltage or differential voltage to the LPC. It should be noted that there are numerous schemes of conveying feedback representing laser power to make a determination of present or impending laser saturations conditions. The detection of the laser current used to make the determination of “laser current too high” is performed as follows. The LPC ensures that the laser will generate the power using the information that is supplied by FS feedback signal. This is done by the controller output signals (I_threshold, I_slope). The signal I_slope within the preferred embodiment is directly proportional to the actual laser current required above the laser threshold. Hence, “laser current too high” is detected by observing the value the controller places on I_slope and reacting when it exceeds a predetermined value. It will be readily apparent to those skilled in the art that other detection schemes can be employed to determine laser saturation levels, such as current sensing devices. It will be further understood by those skilled in the art that multiple lasers can be used within an optical disc recording system and in those instances, Forward Sense 27 will detect the present laser power of the laser. Forward sense in an embodiment of multiple laser sources could be a single detection element for all multiple lasers or multiple sensing elements. Circuitry within LPC 28 provides I_slope and I_threshold signal to the Laser Driver Device Driver 24 that is powered by the 5 volt power supply 22 on the PC.

An alternative embodiment of the invention (especially attractive for blue laser systems) employs the use of a floating laser with a current sinking driver. This allows the blue laser to be tied to a high voltage (e.g. 8V) while the LDD itself can be run from 5V or lower with all the advantages that brings. It should be noted that I-slope is related to the sinking of laser current by the LDD from the laser. It will be readily apparent to those skilled in the art that for multiple laser systems with multi-output laser drivers involving LDD outputs that either source current like FIG. 2a (for example CD and DVD lasers) and sink current like FIG. 2b (say for Blue laser) that a hybrid system can be made where in all cases I-slope reflects the laser current (be it sourced or sinked by the LDD) and hence that the invention works for all lasers.

FIG. 2b is a laser diode circuit as envisioned according to the alternative embodiment and to generate therefrom signals for to focus and tracking embodiment of the invention. It should be pointed out that future configurations of the invention will employ an alternative arrangement similar to that shown in FIG. 2b, and as such FIG. 2b constitutes the best mode envisioned for practicing the invention. As previously detailed in the discussion related to FIG. 2a, the detection of the laser power is performed by a Forward Sense that generates a feedback signal to the Laser Power Control (LPC). The Forward Sense is preferably a photodetector that detects a small linear percentage of the laser output and sends feedback signal to represent the present amount of laser power. The laser diode driver circuit is preferably used for LDD 24 and laser 26 as illustrated in FIG. 2a. The circuit of FIG. 2b uses a current sinking element instead of a current source element. The laser L1 has its' anode connected to the supply voltage VSO with its' cathode connected to the laser current driver 10. The laser current driver 10 sinks current from the laser L1 to ground through the current sinking element. The voltage at the output of the laser current driver 10 is referred to as V₁₀ and is indicated in FIG. 3 with arrow 7. The voltage Vₒᵤₜ is less than the supply voltage VSO because of the voltage drop across the laser L1.

The situation of “laser current too high”, as discussed herein, is an occurrence that has been demonstrated based on experiments. These experiments have been performed at temperatures that are outside the specification for normal use, including very high temperatures in an oven at 65° C. These experiments illustrate that the system can be set up so that the relationship between laser power and I_slope is maintained up to the limit of the write power control signal (I_slope) of the main power controller. The main power controller in the preferred embodiment is located on the main Printed Circuit Board (PCB). The write power control signal (I_slope) usually controls the amount of peak current made in the laser driver above the threshold according to the following relationship:

K*I_slope=Ilaser_peak_total−I_threshold.

Wherein, K is the amplification between I_slope and the LDD output. K is determined by measuring the typical laser power output (above threshold power) versus current and can be fined tuned during drive calibration by relating a given OPU output power to a given value of I_slope. Ilaser_peak_total is the maximum current for the laser and I_threshold is the threshold current for the laser.

In the preferred embodiment, laser peak power (with respect to bias power) is set by an analog reference value for the write power control signal (I_slope) that is sent from the LPC on the main PCB. On the OPU all other power values between the peak value and bias are created by a DAC function driven by control signals from a write strategy generator. This allows the Engine to use the limiting value of I_slope as detection criterion. I_slope is controlled in real-time via the laser power control feedback loop 28 which ensures that the required laser power is made according to a setpoint in a controller that is within LPC 23. The digital value of delta_actual that is read is used within the preferred embodiment, as detection criterion by the invention. The saturation threshold limit is reached once delta_actual hits the Max Allowable Value, which in the preferred embodiment is about 2.5 mA. In the preferred embodiment, Max Allowable Value is set a binary value of 250 within an 8-bit system. Numerous variations of the foregoing will be readily apparent to those skilled in the art, including but not limited to different Max Allowable Values for various lasers and different digital representations of Max Allowable Value. In order to achieve robustness, a number of samples of delta_actual are taken for any of the given check points and only once a certain percentage of these are at (or above) the Max Allowable Value, will the callback be activated by indicating that “laser current too high”. Preferably, the average of a number of delta_actual samples is be created and compared against the Max Allowable Value. Alternatively, a medium value a number of delta_actual samples could also be used.

Preferably, after Check delta_actual 32 is performed, the system compares the average value of a number of delta_actual samples against the threshold (the Max Allowable Value) at step 34 to detect if the condition of laser current is too high exists. If laser current is too high exists, then a branch is made to Callback to DataPath 36 which sends a callback to the Datapath via the “laser current too high” bit in the Application Program Interface (API) interface. Once the system initiates a callback due to detecting “laser current too high”, then the DataPath should respond by a spin-down procedure.

FIG. 4 is a flowchart illustrating the preferred manner of implementing Check delta_actual 40. Read delta actual and store 42 samples laser current levels for 15 different samples of laser current. Once 15 samples are taken, then decision block 44 passes operation to Calculate Average 46 which computes the average of the 15 samples for laser current. If the average value is greater than a predetermined threshold, then Callback to Datapath 36 initiates a spin down algorithm.

FIG. 5 is a flow diagram the routine that is perform by Callback to Datapath initiated in FIG. 3 that performs a spin down of the optical disc as envisioned by the present invention. The Callback to Datapath is entered at reference numeral 50 upon a determination that the laser current is at a level that is about to, or already has, driver the laser into saturation. Once the spin down algorithm is entered 50, then Laser Current too High Interrupt Set 52 checks to verify if an interrupts has been set indicating that a situation of potential laser saturation has been detected. Once Laser Current too High Interrupt Set 52 verifies that this interrupt is set, Execute Spin Down 54 is performed. Execute Spin Down 54 will change the writing speed in accordance with the writing speed control strategy that is being employed for the optical disc writing system. In the case of a CAV strategy, the present speed is preferably held and a transition is made to a CLV writing mode. Once Execute Spin Down 54 is performed Clear “Laser Current too High” Interrupt resets the interrupt and processing ends 58 and a returned is made as indicated in FIG. 3.

The present invention has applications in optical writing systems, particularly high speed data writing systems such as blue laser based systems. It is envisioned that the present invention can be implemented in single writer based systems, and multiple writer based systems. It is further envisioned that the invention that multiple writer based systems can be implemented using blue, green red, infra-red or any combination of lasers.

The forgoing describes the embodiments most preferred by the inventor for practicing the invention. Variations of the foregoing embodiments will be readily apparent to those skilled in the art; therefore, the scope of the invention should be measured by the appended claims.

1. A method for controlling laser current and power within an optical recording system with laser light being incident upon a spinning optical media comprising:
monitoring (27) at least one laser (26) and generating a signal (28) indicative of the laser power being made by the laser;
measuring (32) the signal against a predetermined (34) value indicative of laser saturation; and
controlling current (36) within the laser such that current consumed by the laser does not enter laser saturation or voltage saturation regions

2. The method of claim 1 wherein controlling further comprises employing a known relationship between a control signal and current used by the at least one laser.

3. The method of claim 2 wherein the employing the known relationship between the control signal and current used by the at least one laser further comprises a laser saturation level occurring at a given level of the control signal.

4. The method of claim 1 wherein lowering the power setpoint further comprises reducing the writing speed.

5. The method of claim 1 wherein the step of monitoring further comprises detecting light from the laser and generating a feedback representative of the at least one laser power.

6. The method of claim 1 wherein controlling further comprises lowering a power setpoint for the at least one laser.

7. The method of claim 1 wherein the step of monitoring further comprises detecting a voltage level and generating a feedback representative of current being consumed by the laser to be compared with the predetermined value.

8. The method of claim 1 wherein the step of monitoring further comprises a current level sensor that monitors current within the laser and generates a feedback representative of current being consumed by the laser to be compared with the predetermined value.

9. The method of claim 1 wherein step of controlling current further comprises slowing the spinning optical media.

10. The method of claim 1 wherein step of controlling current further comprises slowing the spinning optical media and a slowing of writing onto the optical disc media such that the predetermined value is not exceeded.

11. The method of claim 1 wherein step of controlling control current further comprises slowing the spinning optical media gradually such that writing can be maintained.

12. The method of claim 1 wherein step of controlling current further comprises slowing the spinning optical media such that the linear writing speed is held constant.

13. The method of claim 1, wherein the step of controlling current further comprises altering the predetermined value in accordance with at least one of a set of predetermined parameters.

14 The method of claim 13, wherein altering the predetermined value further comprises altering the predetermined value in real time in response to the at least one of the set of predetermined parameters.

15. An optical recording system comprising:
at least one laser (26) arranged with optics to place a focused light spot on an optical media;
a sensor (27) configured to detect power being produced by the at least one laser device (26) and generate a signal (2) representing power being produced by the laser;
a measuring device (23) that determines if the signal indicates that the at least one laser is approaching saturation; and
a laser current control device (24) that maintains current within the at lest one laser such that current within the at least one laser does not reach saturation.

16. The system of claim 15 wherein the sensor further comprises a photodetector that generates a current from laser light, the current being representative of power of the at least one laser.

17 The system of claim 15 wherein the sensor further comprises a voltage level sensor that generates the signal indicative of current being consumed by the at least one laser.

18. The system of claim 15 wherein the sensor further comprises a current level sensor that generates the signal indicative of current being consumed by the at least one laser.

19. The system of claim 15 further comprising a routine that is called if the measuring device determines that the at least one laser is approaching saturation, wherein the routine slows of the spinning optical media and slows of writing onto the optical disc media.

20. The system of claim 15, wherein the routine further comprises altering at least one of a set of predetermined parameters that is used by the measuring device to determine is the at least one laser is approaching saturation, wherein altering the measuring device alters the at least one of the set of predetermined parameters in real time.
